(19) United States
(12) Patent Application Publication
(10) Pub. No.: US 2024/0322086 A1
(43) Pub. Date: Sep. 26, 2024

(54) ULTRAVIOLET LIGHT-EMITTING DIODE AND LIGHT-EMITTING DEVICE INCLUDING THE SAME

(71) Applicant: QUANZHOU SANAN SEMICONDUCTOR TECHNOLOGY CO., LTD., Quanzhou (CN)

(72) Inventors: Bin JIANG, Quanzhou (CN); Siyi LONG, Quanzhou (CN); Yashu ZANG, Quanzhou (CN); Kang-Wei PENG, Quanzhou (CN); Weichun TSENG, Quanzhou (CN); Sihe CHEN, Quanzhou (CN); Mingchun TSENG, Quanzhou (CN)

(21) Appl. No.: 18/680,674

(22) Filed: May 31, 2024

Related U.S. Application Data
(63) Continuation-in-part of application No. PCT/CN2021/135485, filed on Dec. 3, 2021.

(51) Int. Cl. H01L 33/46; H01L 33/32; H01L 33/42; H01L 33/44

(52) U.S. Cl. CPC H01L 33/46; H01L 33/32; H01L 33/42; H01L 33/44

(57) ABSTRACT

An ultraviolet light-emitting diode includes a semiconductor layered stack, an ohmic contact layer, a metal current spreading layer, and a reflective layer. The semiconductor layered stack includes a first semiconductor layer having a first conductivity, a second semiconductor layer having a second conductivity, and an active layer disposed between the first semiconductor layer and the second semiconductor layer, and generating light by electron-hole recombination. The ohmic contact layer is formed on the second semiconductor layer, and forms an ohmic contact with the second semiconductor layer. The metal current spreading layer is formed on the ohmic contact layer, and electrically connected to the second semiconductor layer through the ohmic contact layer. The reflective layer is formed on the metal current spreading layer, and covers an exposed surface of the second semiconductor layer. A light-emitting device including the ultraviolet light-emitting diode is also provided.

### CROSS-REFERENCE TO RELATED APPLICATION

This application is a continuation-in-part (CIP) of International Application No. PCT/CN2021/135485, filed on Dec. 3, 2021, the entire disclosure of which is incorporated by reference herein.

### FIELD

The disclosure relates to a light-emitting diode and a light-emitting device including the light-emitting diode, and more particularly to an ultraviolet light-emitting diode and a light-emitting device including the same.

### BACKGROUND

In recent years, ultraviolet (UV) light-emitting diodes (LEDs), particularly deep UV LEDs, are becoming known to people because of having great application value, so they have attracted great attention in the related fields and hence have become a focus of research. In order to allow a current to be uniformly injected into a light-emitting layer of an LED element, in a conventional UV LED chip, a transparent conductive oxide layer, e.g., an indium-tin-oxide (ITO) layer or an indium-zinc-oxide (IZO) layer, is usually provided to form on a surface of a p-type semiconductor layer thereof to serve as a current spreading layer, thereby allowing the current to successfully spread into the light-emitting layer. However, the ITO layer has a problem of serious light absorption at UV wavelengths, especially in a deep UV wavelength range. Referring to FIG. 7, light absorption rates at different light wavelengths in different ITO layers having different thicknesses are shown. It can be seen from FIG. 7 that the commonly used one of the ITO layers with a thickness of 110 nm, shows an absorption rate up to over 80% at light wavelengths below 280 nm. Consequently, it is difficult to effectively increase light brightness for an UV LED with such commonly used ITO layer therein.

### SUMMARY

Therefore, an object of the disclosure is to provide an ultraviolet light-emitting diode and a light-emitting device including the same that can alleviate at least one of the drawbacks of the prior art.

According to a first aspect of the disclosure, the ultraviolet light-emitting diode includes a semiconductor layered stack, an ohmic contact layer, a metal current spreading layer, and a reflective layer.

The semiconductor layered stack includes a first semiconductor layer having a first conductivity, a second semiconductor layer having a second conductivity different from the first conductivity, and an active layer disposed between the first semiconductor layer and the second semiconductor layer, and generating light by electron-hole recombination. The ohmic contact layer is formed on the second semiconductor layer, and forms an ohmic contact with the second semiconductor layer. The metal current spreading layer is formed on the ohmic contact layer, and electrically connected to the second semiconductor layer through the ohmic contact layer. The reflective layer is formed on the metal current spreading layer, and covers an exposed surface of the second semiconductor layer.

According to a second aspect of the disclosure, the light-emitting device includes the aforesaid ultraviolet light-emitting diode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view of a first embodiment of an ultraviolet light-emitting diode according to the disclosure.

FIG. 2 is a cross-sectional view of FIG. 1 taken along line A-A.

FIG. 3 is a schematic top view showing an n-type ohmic contact layer of the ultraviolet light-emitting diode of the first embodiment.

FIG. 4 is a schematic top view showing metal current spreading layers of the ultraviolet light-emitting diode of the first embodiment.

FIGS. 5 and 6 show schematic top views showing a reflective layer of the ultraviolet light-emitting diode of the first embodiment, where a shaded portion in FIG. 5 represents a reflection area that overlaps with the active layer, and two shaded portions in FIG. 6 represent the areas that do not overlap with the active layer.

FIG. 7 shows light absorption curves of ITO layers with different thicknesses.

FIG. 8 is a schematic top view of a second embodiment of the ultraviolet light-emitting diode according to the disclosure.

FIG. 9 is a cross-sectional view of FIG. 8 taken along line B-B.

FIG. 10 is a schematic top view of metal current spreading layers of the ultraviolet light-emitting diode of the second embodiment.

FIGS. 11 and 12 show schematic top views of a reflective layer of the ultraviolet light-emitting diode of the second embodiment, where a shaded portion in FIG. 11 represents a reflection area that overlaps with the active layer, and shaded portions in FIG. 12 represent the areas that do not overlap with the active layer.

FIG. 13 shows light reflectivity curves of reflective layers of different light-emitting diodes.

FIG. 14 shows brightness scatter plots of different light-emitting diodes.

FIG. 15 is a cross-sectional view of a third embodiment of the ultraviolet light-emitting diode according to the disclosure.

FIG. 16 shows reflectance curves of different light-emitting diodes.

FIG. 17 shows brightness scatter plots of different light-emitting diodes.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

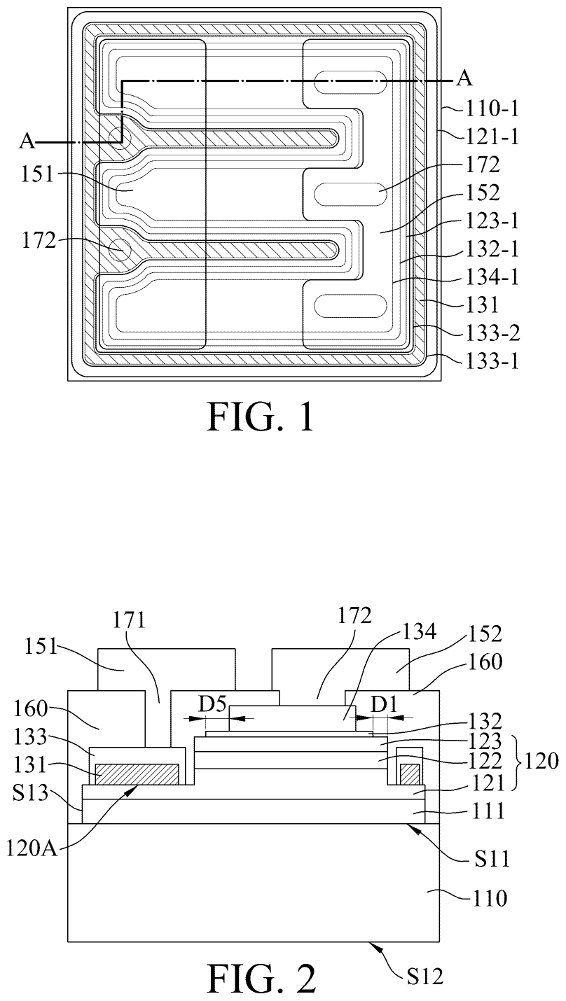

FIG. 1 is a schematic top view of a first embodiment of an ultraviolet light-emitting diode according to the disclosure, and FIG. 2 is a cross-sectional view of FIG. 1 taken along line A-A. The ultraviolet light-emitting diode includes a substrate 110, a semiconductor layered stack 120 formed on an upper surface of the substrate 110, ohmic contact layers 131, 132 (which will be referred to as first ohmic contact layer 131 and second ohmic contact layer 132 hereinafter), metal current spreading layers 133, 134 (which will be referred to as first metal current spreading layer 133 and second metal current spreading layer 134 hereinafter), pad electrodes 151, 152 (which will be referred to as first pad electrode 151 and second pad electrode 152 hereinafter), and a reflective layer 160. In this embodiment, the ultraviolet light-emitting diode is a flip chip with a light extraction surface (S12) on one side of the substrate 110.

The substrate 110 serves to support the semiconductor layered stack 120, and has a first surface (S11) and the light extraction surface (S12). The first surface (S11) is a forming surface of the semiconductor layered stack 120. The light extraction surface (S12) is opposite in position to the first surface (S11). The substrate 110 may be, for example, a sapphire substrate. Alternatively, the substrate 110 can be a growth substrate capable of forming a Group III-nitride semiconductor film. In some embodiments, the substrate 110 is made of a transparent material or a translucent material. In order to enhance light extraction efficiency, particularly efficiency of light extraction from the light extraction surface (S12) of the substrate 110, in some embodiments, the substrate 110 is made with an increased thickness that may range from 250 μm to 900 μm.

In some embodiments, a bottom layer 111 made of aluminum nitride is formed on the first surface (S11) of the substrate 110, that is to say, the bottom layer 111 is in contact with the first surface (S11). In addition, the bottom layer 111 may have a thickness of less than or equal to 1 μm, and moreover, may include a low-temperature layer, an intermediate layer, and a high-temperature layer in that order on the first surface (S11) of the substrate 110 to enable growth of the semiconductor layered stack 120 with excellent crystallinity. In other embodiments, the aluminum nitride bottom layer 111 is formed with multiple holes therein beneficial for relief of stress from the semiconductor layered stack 120. The holes may be a series of elongated holes extending along a thickness of the bottom layer 111, and has a depth of, for instance, 0.5 μm to 1.5 μm.

The semiconductor layered stack 120 is formed on the bottom layer 111, and includes a first semiconductor layer 121, a second semiconductor layer 123, and an active layer 122 disposed therebetween and generating light by electron-hole recombination. The first semiconductor layer 121 may be, for example, an n-type layer, and the second semiconductor layer 123 may be, for instance, a p-type layer. In other words, the first semiconductor layer 121 may have a first conductivity, and the second semiconductor layer 123 may have a second conductivity different from the first conductivity. Additionally, the n-type layer and the p-type layer may be interchanged. Specifically, the first semiconductor layer 121 may be an n-type aluminum gallium nitride (AlGaN) layer. The active layer 122 is an ultraviolet light-emitting layer, and includes well layers and barrier layers which are alternately stacked with the number of repeating cycles ranging between 1 and 10. The well layers and barrier layers may be AlGaN layers. In addition, the light emitted by the active layer 122 may have a central wavelength ranging from 220 nm to 400 nm. However, the wells layers have an aluminum (Al) content lower than that in the barrier layers. The second semiconductor layer 123 may be a p-type AlGaN layer, a p-type GaN layer, or a stack of alternating p-type AlGaN layers and p-type GaN layers. In some embodiments, the second semiconductor layer 123 may include the p-type AlGaN layer and the p-type GaN layer, and the p-type GaN layer has a thickness of less than or equal to 50 nm. In this embodiment, the second semiconductor layer 123 includes a p-type GaN surface layer which has a thickness within a range from 5 nm to 50 nm. By designing the p-type GaN surface layer with such a thin film, internal and external quantum luminescence efficiencies of the light emitting diode may be improved. To be more specific, the p-type GaN surface layer having the thickness within the foregoing range facilitates lateral spreading of a p-side current without causing excessive light absorption.

Referring to FIGS. 1 and 2, in this embodiment, there is a distance present between a periphery 121-1 of the first semiconductor layer 121 and a periphery 110-1 of the substrate 110, and the periphery 121-1 (or sidewall) of the first semiconductor layer 121 is located inside of the periphery 110-1 (or sidewall) of the substrate 110. It should be noted that increasing the thickness of the substrate 110 is beneficial to enhancing luminous efficiency of the ultraviolet light-emitting diode, but an increase in thickness of the substrate 110 may increase difficulty in cutting of the substrate 110. In this embodiment, by maintaining a certain distance between the periphery 121-1 of the first semiconductor layer 121 and a periphery 110-1 of the substrate 110, it can be ensured that the semiconductor layered stack 120 will not be damaged during cutting of the substrate 110, thereby improving the reliability of the ultraviolet light-emitting diode. In certain embodiments, the distance therebetween may be greater than or equal to 2 μm. For example, the distance may range from 4 μm to 10 μm.

As shown in FIGS. 1 and 2, a portion of the semiconductor layered stack 120 is removed (i.e., part of the second semiconductor layer 123 and part of the active layer 122 in the semiconductor layered stack 120 are removed), so as to expose the first semiconductor layer 121, thereby forming one or more mesas 120A. In this embodiment, the ultraviolet light-emitting diode is formed with a plurality of the mesas 120A, which are used to form the first ohmic contact layer 131 thereupon. Distribution of the mesas 120A is not limited to that shown in FIG. 2, and can be designed based on an actual size and shape of the ultraviolet light-emitting diode. Additionally, the mesas 120A can be connected to each other or separated from each other. In the ultraviolet light-emitting diode, the n-type layer usually has a high Al content, which causes difficulty for spreading of high current, and makes it hard for the current to flow uniformly in the active layer 122 and the p-type layer. In this embodiment, the mesas 120A in the ultraviolet light-emitting diode may have a surface area that accounts for 20% to 50% of a total surface area of the semiconductor layered stack 120, and may be distributed in the semiconductor layered stack 120 in a relatively even manner. In certain embodiments, a shortest distance between the active layer 122 to the mesas 120A may be kept within a range from 4 μm to 15 μm, so as to improve current spread in the n-type layer, as well as to enhance an internal quantum efficiency of the ultraviolet light-emitting diode, thereby reducing a forward voltage of the ultraviolet light-emitting diode. When the surface area of the mesas 120A is too large, the active layer 122 is likely to lose much area, and the luminous efficiency of the ultraviolet light-emitting diode may become hard to improve.

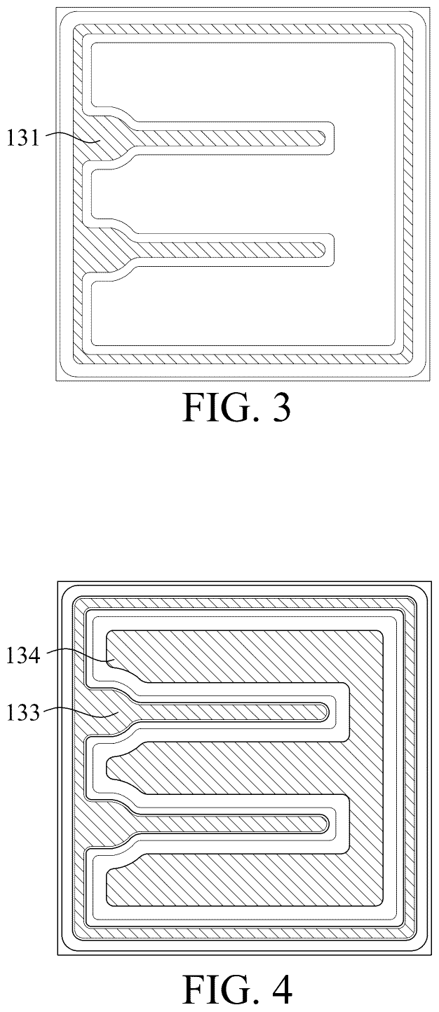

It can be seen from FIGS. 2 and 3 that the first ohmic contact layer 131 is formed in direct contact with the mesas 120A, and forms an ohmic contact with the first semiconductor layer 121. The first ohmic contact layer 131 may be made of a material selected from the group consisting of chromium (Cr), platinum (Pt), gold (Au), nickel (Ni), titanium (Ti), aluminum (AI), and combinations thereof. Since the first semiconductor layer 121 may have a relatively high Al content, the first ohmic contact layer 131, after being deposited on the mesas 120A, still needs to be fused at a high temperature to form into an alloy, so as to form a good ohmic contact with the first semiconductor layer 121. Examples of the alloy are a Ti—Al—Au alloy, a Ti—Al—Ni—Au alloy, a Cr—Al—Ti—Au alloy, and a Ti—Al—Au—Pt alloy.

The second ohmic contact layer 132 is formed in contact with a surface of the second semiconductor layer 123, and forms an ohmic contact therewith. In some embodiments, the second ohmic contact layer 132 may be made of a transparent conductive oxide, or may be made of a metal alloy, such as a NiAu alloy, a nickel silver (NiAg) alloy, or a nickel rhodium (NiRh) alloy. In addition, the second ohmic contact layer 132 may have a thickness of less than or equal to 30 nm, which can reduce light absorption rate of the second ohmic contact layer 132 as much as possible. With a transparent or semi-transparent conductive thin film design, the second ohmic contact layer 132 can form a good ohmic contact with the second semiconductor layer 123. In addition, a significant increase in light absorption rate due to an excessively large thickness of the second ohmic contact layer 132 can be avoided. In still some embodiments, a wavelength of light emitted by the active layer 122 is less than or equal to 280 nm, and the second ohmic contact layer 132 is made of indium tin oxide (ITO) and has a thickness ranging from 5 nm to 20 nm. For instance, the thickness of the second ohmic contact layer 132 may range from 10 nm to 15 nm. In such circumstance, the second ohmic contact layer 132 made of ITO may have an absorption rate to light emitted by the active layer 122 lowered to less than 40%. In yet some embodiments, a distance (D1) between a periphery 132-1 of the second ohmic contact layer 132 and a periphery 123-1 of the second semiconductor layer 123 ranges from 2 μm to 15 μm, e.g., from 5 μm to 10 μm. By providing the distance (D1), risks of current leakage (also called “reverse leakage current”; referred to as “IR”) and abnormal electrostatic discharge (ESD) that may happen to the ultraviolet light-emitting diode can be reduced. Furthermore, a distance between an end point (or an edge) of an upper surface of the second ohmic contact layer 132 and an edge of the first ohmic contact layer 131 may be greater than or equal to 4 μm. In some embodiments, the distance therebetween may be greater than or equal to 6 μm. When the distance is too small, current leakage is likely to occur. In still some embodiments, the distance between the end point (or the edge) of the upper surface of the second ohmic contact layer 132 and the edge of the first ohmic contact layer 131 may be greater than or equal to 4 μm and less than or equal to 10 μm. The distance between the end point (or the edge) of the upper surface of the second ohmic contact layer 132 and the edge of the first ohmic contact layer 131 includes a distance between an upper surface of an edge of the first ohmic contact layer 131 and an upper surface of an edge of the second semiconductor layer 123, which is greater than or equal to 2 μm, plus a distance between the edge of the upper surface of the second ohmic contact layer 132 and the upper surface of the edge of the second semiconductor layer 123, which is greater than or equal to 2 μm. With such setting, it can be ensured that the second ohmic contact layer 132 is spaced apart from the mesas 120A of the semiconductor layered stack 120 (an epitaxial structure) by a certain distance, which can prevent current leakage as well as abnormal ESD of the ultraviolet light-emitting diode. In addition, with the forgoing setting, it can also be ensured that an edge of the reflective layer 160 can be spaced apart from the mesas 120A of the epitaxial structure by a certain distance to ensure a sufficient thickness of the reflective layer 160 being disposed on a sidewall of epitaxial structure that has undergone etching and to thereby provide a better insulation quality and a better anti-current leakage ability of the ultraviolet light-emitting diode.

The second metal current spreading layer 134 is formed on the second ohmic contact layer 132 and electrically connected to the second semiconductor layer 123 through the second ohmic contact layer 132, and is used to assist in spread of current to a whole light-emitting area. In certain embodiments. the second metal current spreading layer 134 may be a multi-layered structure which includes, for instance, an adhesion layer and a conductive layer that are sequentially deposited in that order on the second ohmic contact layer 132. The adhesion layer may be a chromium (Cr) layer, and may have a thickness ranging from 1 nm to 10 nm. The conductive layer may be an Al layer, and may have a thickness of greater than or equal to 100 nm, e.g., ranging from 200 nm to 500 nm. The Al layer not only provides a good conductivity, but also has a relatively high reflectivity to ultraviolet light. In some embodiments, the conductive layer may have a reflectivity of greater than or equal to 70% to light emitted by the active layer 122. In still some embodiments, there may be one or more stress buffer layer(s), for example, a stack of alternating Al and Ti layers, inserted inside the conductive layer. In yet some embodiments, an etch termination layer made of Pt and another adhesion layer made of Ti may be further formed on the conductive layer. Moreover, in other embodiments, a first metal current spreading layer 133 may be formed on the first ohmic contact layer 131 as shown in FIG. 4. The first metal current spreading layer 133 and the second metal current spreading layer 134 may be formed in a same processing step, so both may be metal stacks with the same structure. In still other embodiments, the first metal current spreading layer 133 completely covers the first ohmic contact layer 131, so that on the one hand, a height of the first metal current spreading layer 133 can be increased, and on the other hand, the first ohmic contact layer 131 can be protected.

In the ultraviolet light-emitting diode, especially when it is a deep ultraviolet light-emitting diode, a lateral spreading rate of carriers may be relatively low in the semiconductor layered stack 120; so current accumulation is prone to occur at an edge of the second ohmic contact layer 132 that is near the mesas 120A, which may cause local overheating and burning of electrodes, and hence leading to a decrease in reliability and short lifespan of the ultraviolet light-emitting diode. In certain embodiments, the second metal current spreading layer 134 may be retracted from the second ohmic contact layer 132. That is, a periphery 134-1 of the second metal current spreading layer 134 is located inwardly from the periphery 132-1 of the second ohmic contact layer 132, and there is a distance (D5) between the periphery 134-1 and the periphery 132-1. By providing such distance (D5), not only can current spreading be well regulated, but also a product failure due to excessive current accumulation at the edge of the second ohmic contact layer 132 can be reduced. In certain embodiments, the distance (D5) may be greater than or equal to 3 μm, e.g., range from 3 μm to 15 μm, so as to ensure a sufficient distance between the periphery 132-1 of the second ohmic contact layer 132 and the periphery 134-1 of the second metal current spreading layer 134 close to the mesas 120A. Therefore, the problem of burning out the second ohmic contact layer 132 near the mesas 120A may be solved, and the risk of burning during the course of degradation of the ultraviolet light-emitting diode may be reduced, thereby improving reliability of the deep ultraviolet light-emitting diode.

The reflective layer 160 is formed on the first metal current spreading layer 133 and the second metal current spreading layer 134, and covers an exposed surface of the second semiconductor layer 134 that is exposed from the second ohmic contact layer 132 and the second metal current spreading layer 134. The reflective layer 160 also covers a sidewall of the semiconductor layered stack 120 as well as a sidewall (S13) of the mesas 120A, so as to insulate the first metal current spreading layer 133 and the second metal current spreading layer 134. The reflective layer 160 has openings 171, 172 (hereinafter referred to as first openings 171 and second openings 172) from which the first metal current spreading layer 133 and the second metal current spreading layer 134 are exposed, respectively. The reflective layer 160 may be made of a non-conductive material, and in certain embodiments, the non-conductive material may be an inorganic material or a dielectric material. Examples of the inorganic material includes silica gel and glass. Examples of the dielectric material includes aluminum oxide, silicon nitride, silicon oxide, titanium oxide, and magnesium fluoride. Alternatively, the reflective layer 160 may be made of a material selected from the group consisting of silicon dioxide, silicon nitride, titanium oxide, tantalum oxide, niobium oxide, barium titanate, and a combination thereof; the combination may be a distributed Bragg reflector (DBR) formed by alternately stacking two of the above-mentioned materials.

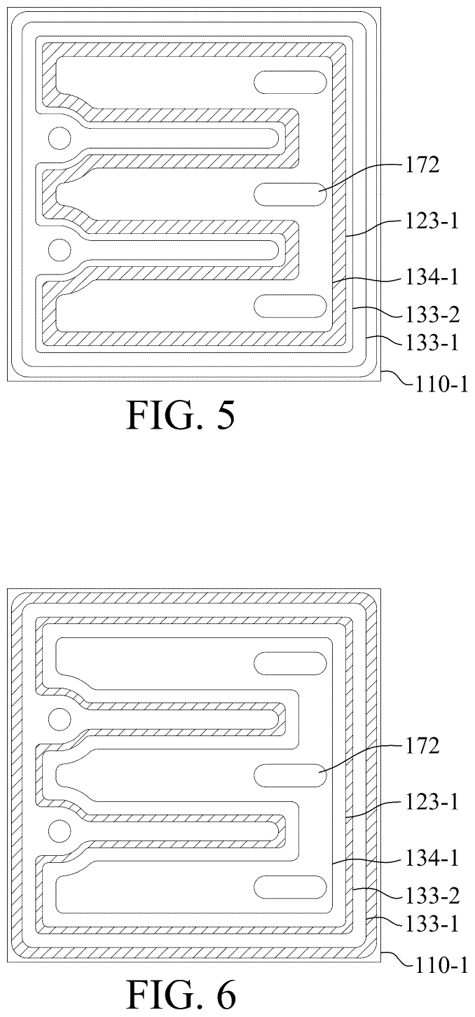

In this embodiment, the reflective layer 160 is an insulating reflective layer. Referring to FIG. 2, the mesas 120A of the ultraviolet light-emitting diode have a relatively large area, and the second metal current spreading layer 134 partially cover the second ohmic contact layer 132. Therefore, by configuring the reflective layer 160 to have a high reflectivity, the light extraction efficiency of the ultraviolet light-emitting diode can be effectively improved. Referring to FIGS. 5 and 6, reflection areas of the ultraviolet light-emitting diode of this embodiment is shown. As shown in FIG. 5, a shaded portion therein represents the reflection area of the insulation layer 60 that overlaps with the active layer 122. Specifically, the reflection area is located between the periphery 123-1 of the second semiconductor layer 123 and the periphery 134-1 of the second metal current spreading layer 134. Light emitted by the active layer 122 toward the second pad electrode 152 can be directly reflected by the reflection area of the reflective layer 160 so as to avoid light absorption below the electrode. In some embodiments, an area of the shaded portion accounts for 5% to 20% of an area of the upper surface of the substrate 110, e.g., 10%. As shown in FIG. 6, two shaded portions therein represent the areas that do not overlap with the active layer 122, and include a first portion located between the periphery 123-1 of the second semiconductor layer 123 and an inner periphery 133-2 of the first metal current spreading layer 133, and a second portion located between an outer periphery 133-1 of the first metal current spreading layer 133 and the periphery 110-1 of the substrate 110. That is to say, the first and second portions in FIG. 6 are around the mesas 120A, and in some embodiments, an area of the two shaded portions accounts for 15% to 40% of the area of the upper surface of the substrate 110, e.g., 25%.

The first pad electrode 151 and the second pad electrode 152 are disposed on the reflective layer 160. The first pad electrode 151 is electrically connected to the first metal current spreading layer 133 through the first opening 171, and the second pad electrode 152 is electrically connected to the second metal current spreading layer 134 through the second opening 172. The first pad electrode 151 and the second pad electrode 152 can be formed using a same material and in a same processing step; so both may be identical in structure. Each of the first pad electrode 151 and the second pad electrode 152 may be made of a material selected from the group consisting of Cr, Pt, Au, Ni, Ti, Al, a gold-tin (AuSn) alloy, and combinations thereof.

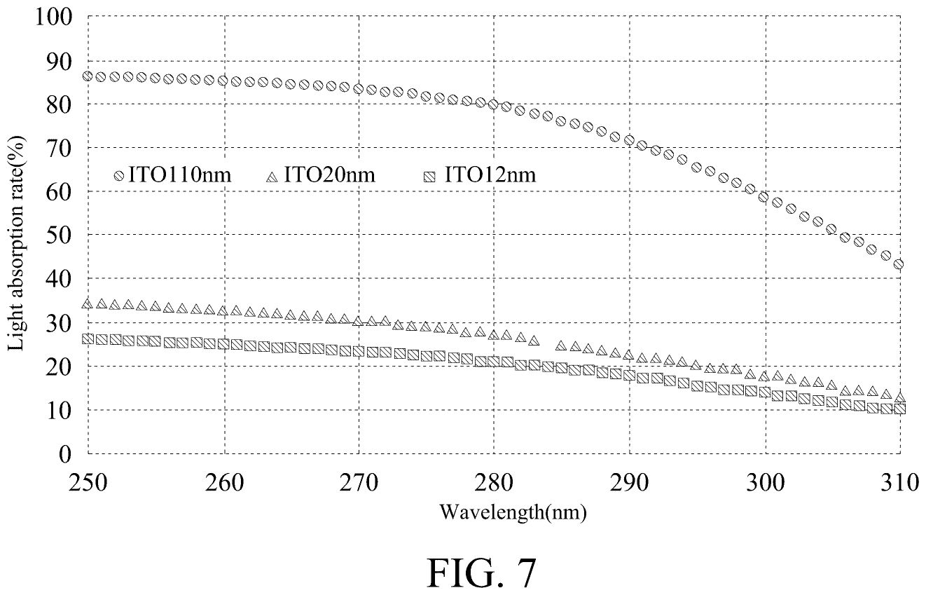

FIG. 7 shows a relationship between thickness and light absorption rate of an ITO layer. When ITO is used for making a current spreading layer, a sufficient thickness is required. Generally, a required thickness is greater than or equal to 100 nm, e.g., 110 nm, but such thickness has a high absorption rate to light in an ultraviolet wavelength range, causing difficulty in increasing luminous efficiency of a light-emitting diode. By designing the second ohmic contact layer 132 with a thin-film structure with the thickness of less than or equal to 30 nm to make ohmic contact with the second semiconductor layer 123, absorption of light from the active layer 122 by the second ohmic contact layer 132 may be reduced. For example, when the second ohmic contact layer 132 is made of ITO and has a thickness of 11 nm, it has a light absorption rate of less than 30% for an ultraviolet light with a wavelength of not greater than 310 nm. Moreover, by adopting the metal current spreading layers 133, 134 with high light reflectivity, current spreading and light reflection can be improved. Furthermore, by providing the reflective layer 160 with a highly reflective structure, light from the active layer 122 can be reflected back through areas of the reflective layer 160 that do not cover the first metal current spreading layer 133 and the second metal current spreading layer 134, thereby enhancing the luminous efficiency of the ultraviolet light-emitting diode.

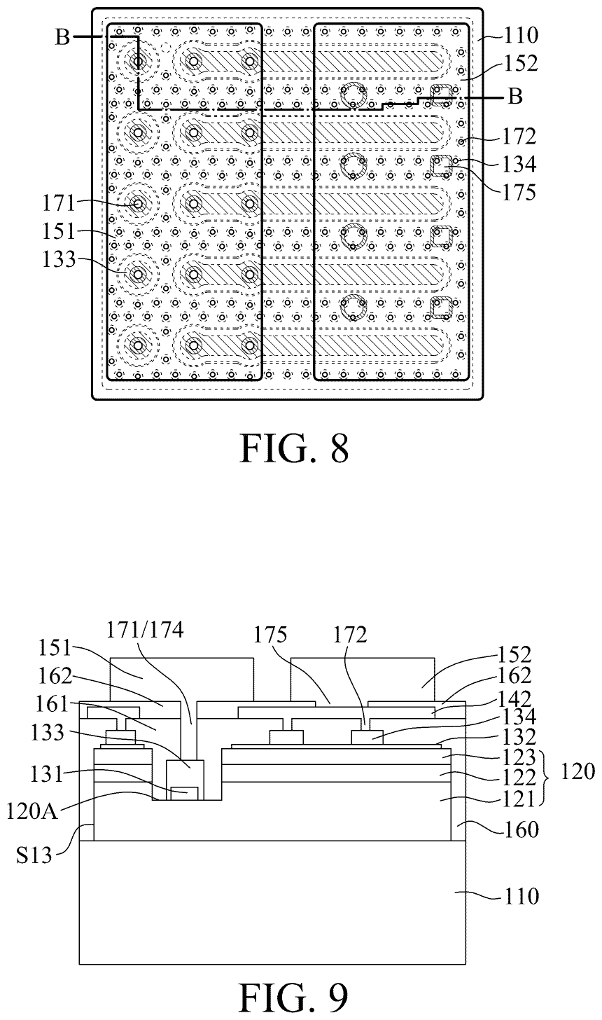

FIG. 8 is a schematic top view of a second embodiment of an ultraviolet light-emitting diode according to the disclosure, and FIG. 9 is a cross-sectional view of FIG. 8 taken along line B-B. The differences between this embodiment and the first embodiment is that the second metal current spreading layer 134 herein is a structure having densely distributed dots. By using the second metal current spreading layer 134 having the densely distributed dots in cooperation with the reflective layer 160 with high reflectivity, luminous efficiency of the ultraviolet light-emitting diode can further be improved.

Specifically, the ultraviolet light-emitting diode includes the substrate 110, the semiconductor layered stack 120 formed on the substrate 110, the first ohmic contact layer 131, the second ohmic contact layer 132, the first metal current spreading layer 133, the second metal current spreading layer 134, connection electrodes (hereinafter referred to as first connection electrode (not shown) and second connection electrode 142), the first pad electrode 151, the second pad electrode 152, the reflective layer 160, and a protective insulation layer 162. Disposition of the substrate 110, the semiconductor layered stack 120, the first ohmic contact layer 131, and the second ohmic contact layer 132 is described hereinbefore with reference to the first embodiment. The ultraviolet light-emitting diode in this embodiment is more suitable for a medium-or large-sized light emitting diode chip, for instance, a chip with a side length of greater than 20 mm. In this embodiment, the semiconductor layered stack 120 includes a plurality of mesas 120A that are separated from each other and distributed within the semiconductor layered stack 120. In certain embodiments, at least one of the mesas 120A is in a finger-shaped pattern. The first ohmic contact layer 131 is formed on the mesas 120A, and forms the ohmic contact with the first semiconductor layer 121. The second ohmic contact layer 132 is formed on the second semiconductor layer 123, and forms the ohmic contact therewith.

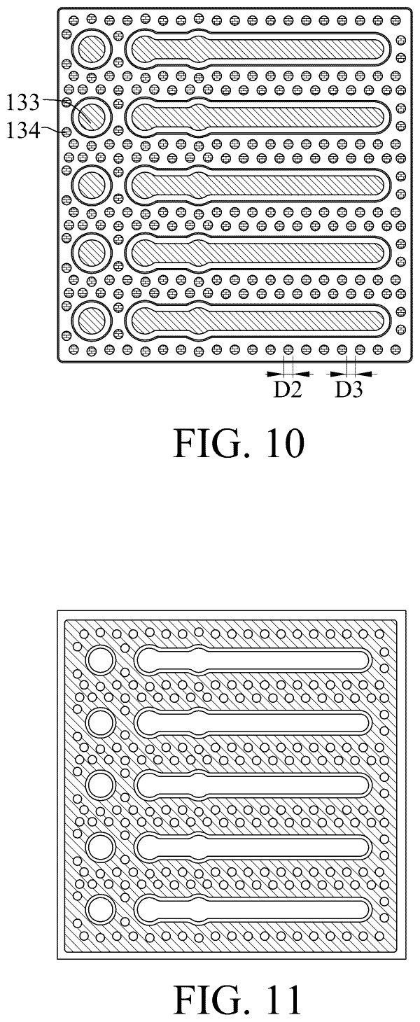

Referring to FIGS. 9 and 10, the second metal current spreading layer 134 is formed on the second ohmic contact layer 132, and includes metal dots that are densely distributed and arranged in an array. In addition, part of the second ohmic contact layer 132 is exposed from the metal dots. Each of the metal dots may have a diameter (D2) ranging from 10 μm to 50 μm, and a distance (D3) between any two adjacent ones of the metal dots may range from 10 μm to 100 μm, so that the metal dots are capable of facilitating current spreading. When the diameter (D2) is less than 10 μm, a contact resistance between the metal dots and second ohmic contact layer 132 may be increased, thereby increasing a forward voltage. When the distance (D3) is less than 10 μm, it is hard to reserve a sufficient area for light reflection. Moreover, when the diameter (D2) exceeds 50 μm, or the distance (D3) exceeds 100 μm, it is difficult to densely distribute the metal dots, resulting in poor uniformity of current spreading, and making current spreading ineffective. In certain embodiments, the diameter (D2) of the metal dots ranges from 15 μm to 35 μm, and the distance (D3) between any two adjacent ones of the metal dots ranges from 15 μm to 35 μm. Within the foregoing ranges, the metal dots can attain the current spreading effect, a sufficient light reflection area can be reserved, and light absorption by the metal dots can be reduced. In this embodiment, a desired forward voltage of the ultraviolet light-emitting diode can be guaranteed by controlling the distance (D3) between any two adjacent ones of the metal dots. The metal dots may be designed as a multi-layered structure as described hereinbefore with reference to the metal current spreading layer 134 of the first embodiment. Furthermore, the first connection electrode (not shown) and/or the first metal current spreading layer 133 is formed on the first ohmic contact layer 131, by which, on the one hand, the first ohmic contact layer 131 can be protected, and on the other hand, height above the mesas 120A may be increased.

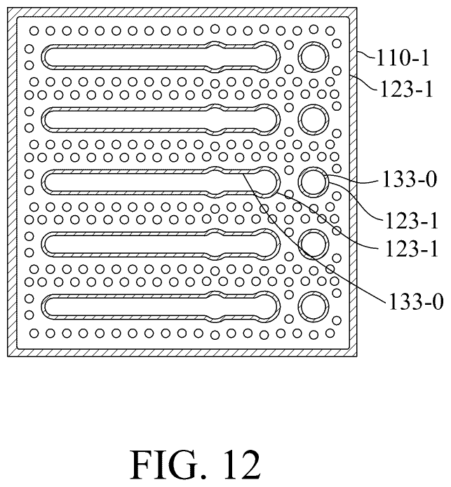

The reflective layer 160 is formed on the first connection electrode (not shown) and the second metal current spreading layer 134, and covers the side of the semiconductor layered stack 120 as well as the side (S13) of the mesas 120A, so as to insulate the first connection electrode (not shown)/the first metal current spreading layer 133 and the second metal current spreading layer 134. The reflective layer 160 has the first openings 171 and the second openings 172. The first openings 171 expose the first connection electrode (not shown) or the first metal current spreading layer 133. Each of the second openings 172 is aligned with one of the metal dots of the second metal current spreading layer 134. To be more specific, each second opening 172 is located vertically above and exposes one of the metal dots. In some embodiments, the reflective layer 160 may include high-refractive index layers and low-refractive index layers which are alternately stacked. In still some embodiments, the reflective layer 160 is an insulating reflective layer which may be made of, for instance, aluminum oxide, silicon nitride, silicon oxide, titanium oxide, magnesium fluoride, or hafnium dioxide. Moreover, the second connection electrode 142 is formed on the insulating reflective layer, and electrically connected to the metal dots through the second openings 172. Referring to FIGS. 11 and 12, a reflection area of the ultraviolet light-emitting diode of this embodiment is shown. As shown in FIG. 11, a shaded portion therein represents the reflection area that overlaps with the active layer 122, and specifically, the reflection area equals to a top surface area of the second semiconductor layer 123 minus areas of the metal dots of the second metal current spreading layer 134. This reflection area can directly reflects light emitted by the active layer 122 toward the pad electrode, so as to avoid light absorption below the pad electrode. In some embodiments, an area of the shaded portion is greater than 30% of the area of the upper surface of the substrate 110, e.g., ranging from 40% to 70%. As shown in FIG. 12, shaded portions therein represent the areas that do not overlap with the active layer 122, and include, a first portion located between the periphery 123-1 of the second semiconductor layer 123 and a periphery 133-0 of the first metal current spreading layer 133, and a second portion located between the periphery 123-1 of the second semiconductor layer 123 and the periphery 110-1 of the substrate 110. That is to say, the shade portions in FIG. 12 are around the mesas 120A, and in some embodiments, an area of the shaded portions accounts for 15% to 30% of the area of the upper surface of the substrate 110, e.g., 15%.

The first connection electrode (not shown) is electrically connected the n-type first ohmic contact electrode 131. The second connection electrode 142 is formed on the reflective layer 160, and is connected to the second metal current spreading layer 134 through the second openings 172, thereby electrically interconnecting all of the metal dots together and hence improving current spreading. Moreover, the second connection electrode 142 may have high reflective capability, so as to complement a large angle reflection ability of the first insulation layer 161, thereby further improving light extraction efficiency of the ultraviolet light-emitting diode. In other embodiments, the first connection electrode (not shown) may also be formed on the first metal current spreading layer 133, so as to reduce height difference between different electrodes and to facilitate setting of the pad electrodes 151, 152 subsequently.

The protective insulation layer 162 is formed on the first connection electrode (not shown) and the second connection electrode 142, so as to electrically insulate the second connection electrode 142 and the first connection electrode (not shown) or the first metal current spreading layer 133. In addition, the second insulation layer 162 has openings 174, 175 (hereinafter referred to as fourth opening 174 and fifth opening 175), and the fourth opening 174 is located in position corresponding to the first opening 171. The first pad electrode 151 and the second pad electrode 152 are formed on the protective insulation layer 162. The first pad electrode 151 is electrically connected to the first connection electrode (not shown) on the first semiconductor layer 121 through the fourth opening 174, and the second pad electrode 152 is electrically connected to the second connection electrode 142 through the fifth opening 175.

In the ultraviolet light-emitting diode of this embodiment, by allowing the second ohmic contact layer 132 to have the thin-film structure and to form ohmic contact with the second semiconductor layer 123, the problem of light absorption can be effectively alleviated. Moreover, by designing the metal dots that are densely distributed, by using the reflective layer 160 to cover the second ohmic contact layer 132, the metal dots, and part of the semiconductor layered stack 120 that is exposed, and by forming the second connection electrode 142 on the reflective layer 160 to electrically connect all of the metal dots, current spreading effects can be realized. On the one hand, with provision of the metal dots, the reflective layer 160 can have a sufficient reflection area, especially, the reflection area overlaps with the active layer 122, thereby effectively enhancing light reflectivity. On the other hand, since the second openings 172 of the reflective layer 160 are located above the metal dots, the metal dots can also function as an etch termination layer to solve an etching problem that may occur in the reflective layer 160, thereby ensuring reliability of the ultraviolet light-emitting diode.

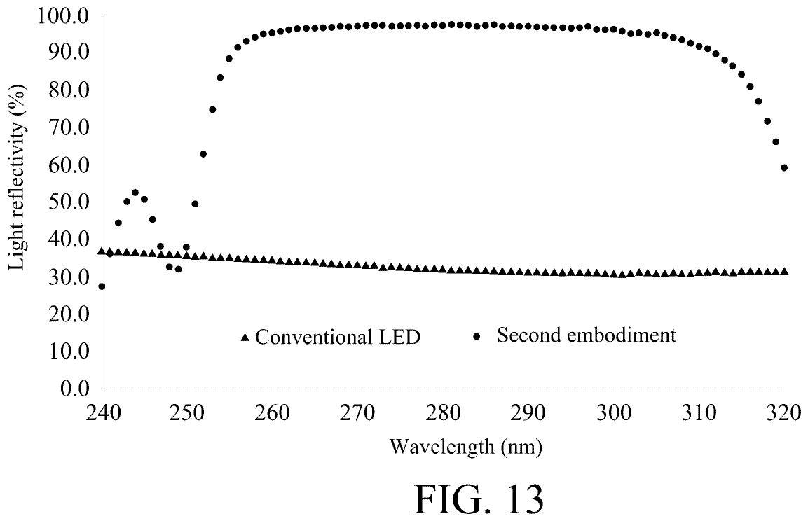

Referring to FIG. 13, a relationship between light reflectivity and light wavelength of the following two light-emitting diodes is shown. The curve with circular dots shows light reflectivities at different wavelengths for the ultraviolet light-emitting diode of the second embodiment according to the disclosure. The second ohmic contact layer 132 adopted therein is made of ITO with a thickness of approximately 11 nm. The second metal current spreading layer 134 includes the metal dots arranged in the array as shown in FIG. 11. The reflective layer 160 is a

DBR reflective layer. The curve with triangular dots shows light reflectivities of a conventional light-emitting diode including an electrode made of a nickel gold (NiAu) alloy at different light wavelengths. The electrode is made by fusion bonding a Ni material with a thickness of about 20 nm and an Au material with a thickness of about 350 nm, and is capable of forming an ohmic contact as well as achieving current spreading effect. As shown in FIG. 13, it can be seen that light reflectivities of the ultraviolet light-emitting diode of the second embodiment reach up to 90% for wavelengths falling within a range from 260 nm to 300 nm, which is much higher than those of the conventional light-emitting diode with the electrode made of NiAu alloy.

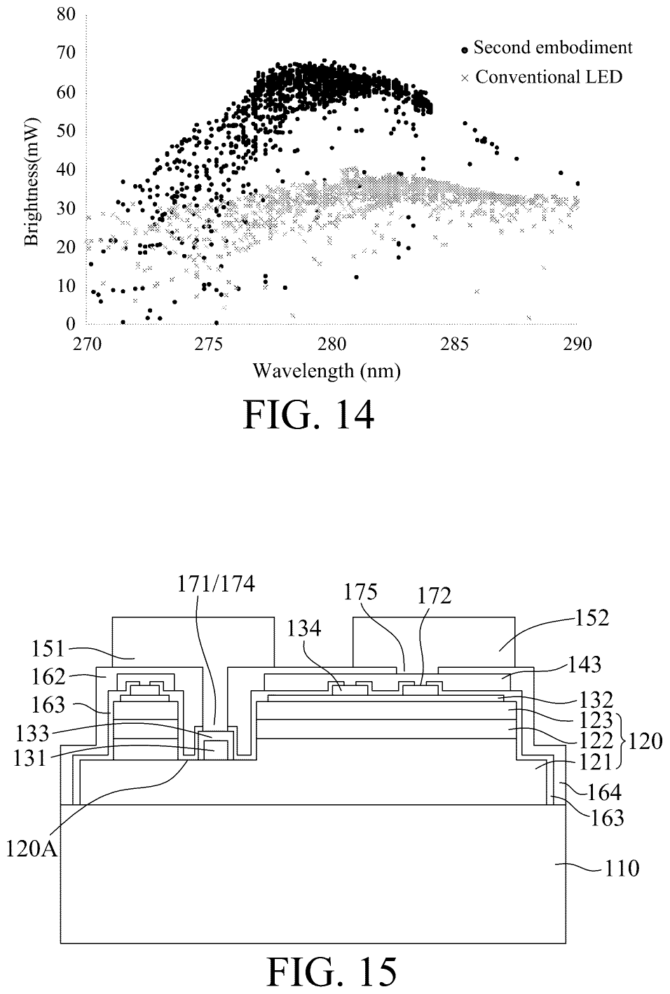

FIG. 14 shows brightness dispersion data obtained at an input current of 350 mA for the above-mentioned two different light-emitting diodes including identical epitaxial structures. The circular dots therein represent brightnesses of the ultraviolet light-emitting diode of the second embodiment according to the disclosure at different light wavelengths. The x dots therein represent brightnesses of the conventional light-emitting diode with the electrode made of the NiAu alloy at different light wavelengths. It can be seen from FIG. 14 that, under the conditions that the two diodes having the same epitaxial structures are tested at the same input current (350 mA), the ultraviolet light-emitting diode of the second embodiment exhibits significantly higher brightness than that of the conventional light-emitting diode.

FIG. 15 is a cross-sectional view of a third embodiment of the ultraviolet light-emitting diode according to the disclosure. It is well known that in a deep ultraviolet light-emitting diode, aluminum shows the best light reflection ability among metals. However, an interface between a pure Al layer and an ITO layer encounters problems, such as poor adhesion and high contact resistance. As a result, in the light-emitting diode industry, a Cr layer is commonly used as an adhesion layer between the ITO layer and the pure Al layer. Nevertheless, using the Cr layer may reduce a reflection effect. Therefore, the ultraviolet light-emitting diode in this embodiment is provided to solve the foregoing problems, and differences between the third and second embodiments are that the reflective layer in the third embodiment is made of Al and is denoted by “143”, and a transparent adhesion layer 163 are disposed between the second ohmic contact layer 132 (i.e., ITO layer) and the reflective layer 143 (i.e., Al layer).

Specifically, the ultraviolet light-emitting diode in this embodiment includes the substrate 110, the semiconductor layered stack 120 formed on the upper surface of the substrate 110, the first ohmic contact layer 131, the second ohmic contact layer 132, the second metal current spreading layer 134, the transparent adhesion layer 163, the reflective layer 143 (i.e., Al layer), the first pad electrode 151, the second pad electrode 152, and a protective insulation layer 164.

The substrate 110, the semiconductor layered stack 120, the first ohmic contact layer 131, and the second ohmic contact layer 132 can be arranged as described hereinbefore with reference to the first embodiment. In addition, the mesas 120A and the densely distributed metal dots are arranged as described hereinbefore with reference to the second embodiment.

The transparent adhesion layer 163 covers the second ohmic contact layer 132, the second metal current spreading layer 134, and the semiconductor layered stack 120. In some embodiments, the transparent adhesion layer 163 in this embodiment is made of an insulation material, so that the first metal current spreading layer 133 and the second metal current spreading layer 134 are insulated from each other. The transparent adhesion layer 163 has the first opening 171 and the second openings 172. In addition, the first opening 171 exposes the first metal current spreading layer 133, and the second openings 172 expose the metal dots of the second metal current spreading layer 134. In other words, each of the metal dots has a corresponding one of the second openings 172 thereupon. The transparent adhesion layer 163 may be made of, for example, aluminum oxide, silicon nitride, silicon oxide, titanium oxide, or magnesium fluoride. In certain embodiments, the transparent adhesion layer 163 is made of silicon dioxide, and has a thickness of less than or equal to 100 nm. The reflective layer 143 (i.e., Al layer) is formed on the transparent adhesion layer 163, and is connected to the second metal current spreading layer 134 through the second openings 172, thereby connecting all of the metal dots together and realizing current spreading effect. In some embodiments, the reflective layer 143 (i.e., Al layer) has a reflectivity to the light emitted by the active layer 122 of greater than or equal to 75%. In other embodiments, an Al layer (not shown) can also be formed on the first metal current spreading layer 133, so as to reduce height difference between different electrodes and to facilitate setting of the pad electrodes 151, 152.

In this embodiment, the reflective layer 143 (i.e., Al layer) may have a thickness of greater than or equal to 80 nm. For instance, the thickness may range from 100 nm to 300 nm, so that not only can a good reflection effect be achieved, but also a good conductive property can be obtained.

In the ultraviolet light-emitting diode of the third embodiment, by allowing the second ohmic contact layer 132 to have the thin-film structure and to form the ohmic contact with the second semiconductor layer 123, the problem of light absorption can be effectively alleviated. Moreover, by designing the metal dots that are densely distributed, by using the transparent adhesion layer 163 to cover the second ohmic contact layer 132 and the metal dots, and by forming the reflective layer 143 (i.e., Al layer) upon the transparent adhesion layer 163, not only the metal dots can be connected together to realize current spreading effect, but also the reflective layer 143 and the transparent adhesion layer 163 can together form an omnidirectional reflector. On the one hand, the metal dots can reserve a sufficient reflection area for light reflection by the reflective layer 143 (i.e., Al layer). Especially, the reserved reflection area overlaps with the active layer 122, thereby effectively enhancing light reflectivity. On the other hand, the metal dots are capable of forming a good ohmic contact with the second ohmic contact layer 132 (i.e., ITO layer), which solves the problem of high contact resistance between the reflective layer 143 (i.e., Al layer) and the second ohmic contact layer 132 (i.e., ITO layer).

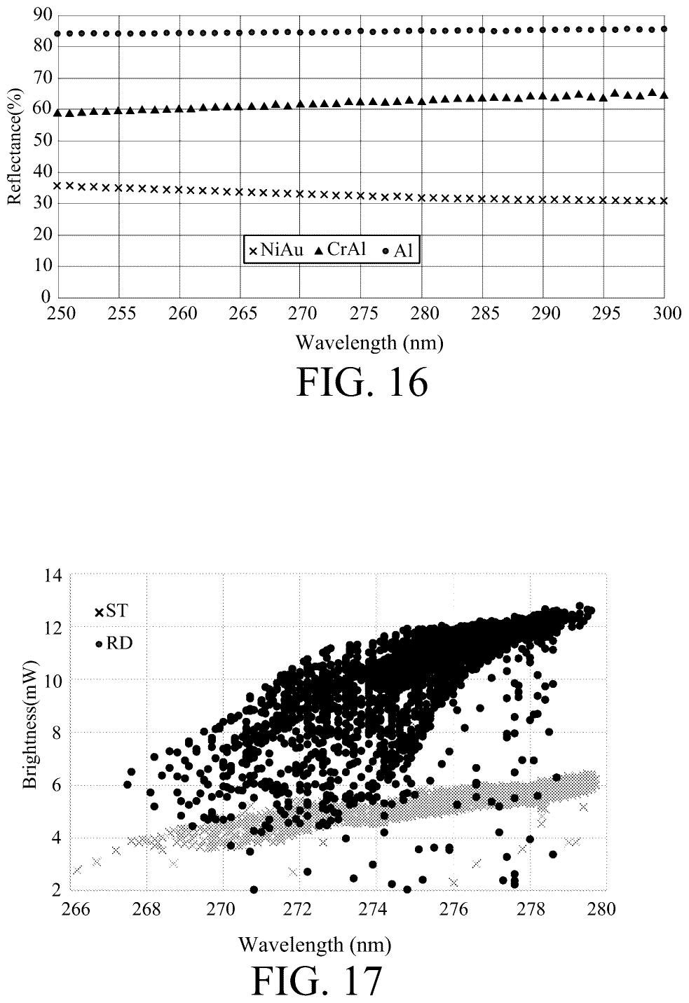

FIG. 16 shows reflectance curves of three different light-emitting diodes. The curve with circular dots shows light reflectivities of the ultraviolet light-emitting diode of the third embodiment according to the disclosure, in which the reflective layer 143 is made of Al. The curve with triangular dots shows reflectivities of a conventional light-emitting diode with an electrode made of a CrAl alloy therein. The curve with x dots shows reflectivities of another conventional light-emitting diode with an electrode made of the NiAu alloy. It can be seen from FIG. 16 that the reflectivities of the ultraviolet light-emitting diode of the third embodiment are greater than 80% at a light wavelength ranging from 260 nm to 300 nm, and therefore are much higher than the reflectivities of the conventional light-emitting diode including the electrode made of the NiAu alloy or the conventional light-emitting diode including the electrode made of the CrAl alloy.

FIG. 17 shows brightness scatter plots obtained from tests that were carried out for two different light-emitting diodes having the same epitaxial structure at an input current of 40 mA. The circular dots therein represent brightnesses of the ultraviolet light-emitting diode of the third embodiment according to the disclosure at different light wavelengths. The x dots therein represent brightnesses of the conventional light-emitting diode with the electrode made of the CrAl alloy. It can be seen from FIG. 17 that under the conditions that the two diodes have the same epitaxial structure and are tested at the same input current (40 mA), the ultraviolet light-emitting diode of the third embodiment according to the disclosure exhibits significantly higher brightness than that of the conventional light-emitting diode including the electrode made of the CrAl alloy.

According to the present disclosure, a light-emitting device including the ultraviolet light-emitting diode of the first embodiment, the second embodiment or the third embodiment is also provided. The light-emitting device may be applied to various ultraviolet (UV) or ultraviolet C (UVC) products.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An ultraviolet light-emitting diode, comprising:
a semiconductor layered stack including a first semiconductor layer having a first conductivity, a second semiconductor layer having a second conductivity different from said first conductivity, and an active layer disposed between said first semiconductor layer and said second semiconductor layer, and generating light by electron-hole recombination;
an ohmic contact layer formed on said second semiconductor layer, and forming an ohmic contact with said second semiconductor layer;
a metal current spreading layer formed on said ohmic contact layer, and electrically connected to said second semiconductor layer through said ohmic contact layer; and
a reflective layer formed on said metal current spreading layer, and covering an exposed surface of said second semiconductor layer.

2. The ultraviolet light-emitting diode as claimed in claim 1, wherein said ohmic contact layer has a thickness of less than or equal to 30 nm.

3. The ultraviolet light-emitting diode as claimed in claim 1, wherein said second semiconductor layer includes an aluminum gallium nitride (AlGaN) layer and a gallium nitride (GaN) layer, said GaN layer having a thickness of less than or equal to 50 nm.

4. The ultraviolet light-emitting diode as claimed in claim 1, wherein said ohmic contact layer is made of a transparent conductive oxide, a distance between a periphery of said ohmic contact layer and a periphery of said second semiconductor layer ranging from 2 μm to 15 μm.

5. The ultraviolet light-emitting diode as claimed in claim 1, wherein said metal current spreading layer is a multi-layered structure which includes an adhesion layer, a conductive layer, and an etch termination layer formed on said ohmic contact layer in that order.

6. The ultraviolet light-emitting diode as claimed in claim 5, wherein said conductive layer has a reflectivity to the light emitted by said active layer, which is greater than or equal to 70%.

7. The ultraviolet light-emitting diode as claimed in claim 1, wherein said metal current spreading layer includes metal dots that are arranged in an array, part of said ohmic contact layer being exposed from said metal dots.

8. The ultraviolet light-emitting diode as claimed in claim 7, wherein said metal dots are uniformly distributed on said ohmic contact layer at intervals ranging from 10 μm to 100 μm.

9. The ultraviolet light-emitting diode as claimed in claim 7, wherein said reflective layer is an insulating reflective layer, said reflective layer covering a side surface of said metal current spreading layer, a side surface of said ohmic contact layer, and a side surface of said semiconductor layered stack, and forming openings each of which is aligned with one of said metal dots.

10. The ultraviolet light-emitting diode as claimed in claim 9, wherein said reflective layer includes high-refractive index layers and low-refractive index layers which are alternately stacked.

11. The ultraviolet light-emitting diode as claimed in claim 1, wherein materials of said reflective layer include silicon dioxide, hafnium dioxide, aluminum oxide, magnesium fluoride, silicon nitride, and titanium oxide.

12. The ultraviolet light-emitting diode as claimed in claim 9, further comprising a connection electrode formed on said insulating reflective layer, and electrically connected to said metal dots through said openings.

13. The ultraviolet light-emitting diode as claimed in claim 7, further comprising a transparent adhesive layer, said transparent adhesive layer covering said metal current spreading layer and said part of said ohmic contact layer that is exposed from said metal dots, said reflective layer being a metal reflective layer formed on said transparent adhesive layer.

14. The ultraviolet light-emitting diode as claimed in claim 13, wherein said metal reflective layer has a reflectivity to the light emitted by said active layer, which is greater than or equal to 75%.

15. The ultraviolet light-emitting diode as claimed in claim 1, wherein the light emitted by said active layer has a central wavelength ranging from 220 nm to 400 nm, and said first semiconductor layer is an n-type AlGaN layer.

16. The ultraviolet light-emitting diode as claimed in claim 15, wherein in said semiconductor layered stack, a portion of said second semiconductor layer and a portion of said active layer are removed so as to expose said first semiconductor layer, thereby forming at least one mesa, said ultraviolet light-emitting diode further comprising an n-type ohmic contact electrode that is formed on said at least one mesa and that forms an ohmic contact with said first semiconductor layer.

17. The ultraviolet light-emitting diode as claimed in claim 16, further comprising a first connection electrode and a second connection electrode, said first connection electrode being electrically connected to said n-type ohmic contact electrode, said second connection electrode being formed on said reflective layer and electrically connected to said metal current spreading layer.

18. The ultraviolet light-emitting diode as claimed in claim 17, further comprising a protective insulation layer, a first pad electrode, and a second pad electrode, said protective insulation layer being formed on said first connection electrode and said second connection electrode, and having openings that respectively expose said first connection electrode and said second connection electrode, said first pad electrode and said second pad electrode being electrically and respectively connected to said first connection electrode and said second connection electrode through said openings.

19. The ultraviolet light-emitting diode as claimed in claim 1, further comprising a substrate, said substrate having a thickness ranging from 250 μm to 900 μm, a distance between a periphery of said first semiconductor layer and a periphery of said substrate being greater than or equal to 2 μm.

20. A light-emitting device, comprising an ultraviolet light-emitting diode as claimed in claim 1.
